(19) United States
(12) Patent Application Publication
(10) Pub. No.: US 2025/0240359 A1
(43) Pub. Date: Jul. 24, 2025

(54) SLIDABLE AND ROLLABLE DEVICE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Yang YANG, Beijing (CN); Huinan SHI, Beijing (CN); Qing GONG, Beijing (CN); Xu LU, Beijing (CN)

(21) Appl. No.: 18/855,489

(22) PCT Filed: Jan. 18, 2024
(86) PCT No.: PCT/CN2024/073011

§ 371 Date: Oct. 9, 2024

(30) Foreign Application Priority Data
Jan. 30, 2023 (CN) 202310095693.6

(51) Int. Cl. H04M 1/02

(52) U.S. Cl. CPC H04M 1/0235; H04M 1/0268

(57) ABSTRACT

A slidable and rollable device includes an outer frame including a fixed frame and a movable frame capable of moving relative to the fixed frame along a first direction, a roller rotatably arranged on the fixed frame, an inner movable plate movably arranged on the fixed frame along the first direction, a driving mechanism arranged on the fixed frame and configured to provide a driving force to the inner movable plate, and a guiding mechanism arranged between the fixed frame and the inner movable plate. The fixed frame includes a first supporting structure. The movable frame includes a second supporting structure. The first side of a flexible display module is arranged on the second supporting structure. The second side of the flexible display module smoothly transits around the outer surface of the roller. The guiding mechanism enables the first supporting structure to move relative to the inner movable plate.

### CROSS-REFERENCE TO RELATED APPLICATIONS

This application is a national phase entry under 35 U.S.C. § 371 of International Application No. PCT/CN2024/073011 filed on Jan. 18, 2024, which claims priority to Chinese patent application No. 202310095693.6, filed with the State Intellectual Property Office of the People's Republic of China on Jan. 30, 2023 and entitled “Slidable and Rollable Device and Display Device”, the entire contents of which are incorporated herein by reference.

### TECHNICAL FIELD

Embodiments of the present disclosure relate to the technical field of display, and in particular to a slidable and rollable device and a display device.

### BACKGROUND

Flexible display screens have the characteristics of being bendable and rollable. By utilizing these characteristics, display devices can be rolled or folded, thereby bringing convenience to people in carrying and using the display devices.

Sliding and rolling forms are another innovative application area of flexible display panels. The forms allow consumers to switch the display areas of the flexible panels at will according to their needs. This is not only convenient for users to carry the flexible panels with them, but also provides users with a better user experience than foldable display panels. Slidable and rollable product is an important direction for the development of flexible display panel. By rolling and opening, the product can be freely converted between mobile phone and tablet, while the screen display has no creases.

### SUMMARY

Embodiments of the present disclosure provide a slidable and rollable device and a display device. The flexible display module is only slightly pulled during the movement of the slidable and rollable device, thereby reducing the risk of interlayer delamination in the flexible display module.

In a first aspect, embodiments of the present disclosure provide a slidable and rollable device for assisting a flexible display module in sliding, rolling-up and opening. The slidable and rollable device includes: an outer frame. The outer frame includes a fixed frame and a movable frame. Along a first direction, the movable frame is configured to move relative to the fixed frame. The fixed frame includes a first supporting structure. The movable frame includes a second supporting structure. The first supporting structure and the second supporting structure are both configured to set the flexible display module. A first supporting surface of the first supporting structure facing the flexible display module is coplanar with a second supporting surface of the second supporting structure facing the flexible display module. The first direction is parallel to both the first supporting surface and the second supporting surface.

The slidable and rollable device includes: a roller. The roller is rotatably arranged on the fixed frame. The outer surface of the roller is used to contact the flexible display module, so that the flexible display module can slide around the roller.

The slidable and rollable device includes: an inner movable plate. The inner movable plate is movably arranged on the fixed frame along the first direction. The flexible display module is provided with a first side and a second side arranged opposite to each other along the first direction. The first side of the flexible display module is arranged on the second supporting structure. The second side of the flexible display module smoothly transits around the outer surface of the roller to a side of the inner movable plate away from the first supporting structure, and is relatively fixed to the inner movable plate, so that the flexible display module maintains a natural bending state.

The slidable and rollable device includes: a driving mechanism arranged on the fixed frame. An output end of the driving mechanism is connected to the inner movable plate, and is used to provide a driving force for the inner movable plate to move along the first direction.

The slidable and rollable device includes: a guiding mechanism arranged between the fixed frame and the inner movable plate and configured for enabling the first supporting structure to move relative to the inner movable plate along the first direction.

Sliding cooperation is used between the fixed frame and the movable frame. The fixed frame is provided with a first supporting structure. The movable frame is provided with a second supporting structure. The first supporting structure and the second supporting structure arranged on the same plane are both used to support the flexible display module. When the movable frame moves relative to the fixed frame, opening and rolling-up of the flexible display module is realized, so that the size of the flexible display module is switched between the mobile phone and the tablet. The flexible display module is provided with a first side and a second side which are arranged opposite to each other. The first side of the flexible display module is arranged on the second supporting structure of the movable frame. The second side of the flexible display module smoothly transits around the outer surface of the roller to the side of the inner movable plate away from the first supporting structure, and is relatively fixed to the inner movable plate. Since the second side of the flexible display module is bent backward and connected to the inner movable plate, the natural reverse warping shape of the flexible display module after bending is maintained. Since the natural reverse warping shape of the flexible display module can also be maintained during an unfolding process, the entire flexible display module is suffered from a smaller force during the unfolding process. When the movable frame moves along the first direction relative to the fixed frame to open the flexible display module, the first side and the second side of the flexible display module move in opposite directions, which can ensure that the flexible display module is only subjected to a small pulling during the movement of the movable frame, thereby reducing the interlayer misalignment of the flexible display module, reducing the risk of interlayer delamination failure of the flexible display module, and further ensuring that the flexible display module will not have poor display during the sliding, rolling-up and opening processes. The driving mechanism provides the inner movable plate with a driving force to move along the first direction, thereby ensuring that the second side of the flexible display module moves stably. In addition, the driving mechanism and the guiding mechanism are both arranged in the outer frame, and the occupation ratio of remaining space in the outer frame is also ensured, which facilitates the design and filling of other modules in the whole machine, and enables more rational use of the space of the slidable and rollable device provided in the present invention, while meeting the position design of the driving mechanism and the guiding mechanism.

In some embodiments, the first supporting structure includes a plurality of first strip-shaped supporting members, and the plurality of first strip-shaped supporting members are arranged in parallel and at intervals along the second direction.

The second supporting structure includes a plurality of second strip-shaped supporting members, the plurality of second strip-shaped supporting members are arranged in cooperation with the plurality of first strip-shaped supporting members, and the plurality of second strip-shaped supporting members are arranged in parallel and spaced apart along a second direction.

The first direction is perpendicular to the second direction.

In some embodiments, at least one second strip-shaped supporting member is distributed in the interval area between any two adjacent first strip-shaped supporting members.

In some embodiments, the guiding mechanism includes: a first rack and a second rack arranged corresponding to the first rack.

The extension direction of the first rack is parallel to the first direction. The first rack is arranged on a side surface of the movable frame away from the first supporting structure. The second rack is arranged on a side surface of the inner movable plate facing the first rack. The orthographic projection of the first rack on the second rack at least partially overlaps with the second rack.

The guiding mechanism further includes: a gear, which is rotatably arranged on the moving frame, is relatively fixed relative to the moving frame, and is meshed with the first rack and the second rack.

In some embodiments, along the second direction, the end surface of the first rack and the end surface of the second rack are flush.

In some embodiments, the number of the first racks is two, and the number of the second racks is two.

The two first racks are arranged at intervals along the second direction, and the two second racks are arranged at intervals along the second direction.

In some embodiments, the driving mechanism includes a driving part and a transmission assembly. The driving part and the transmission assembly are both arranged on the fixed frame.

The driving part is connected with the inner movable plate through the transmission assembly.

In some embodiments, the transmission assembly includes: a screw rod and a fixed seat arranged corresponding to the screw rod. The screw rod extends along the first direction. The fixed seat is arranged on the inner movable plate. The fixed seat is provided with a through hole passing through along the extension direction of the screw rod. The inner wall of the through hole is formed with a screw thread matching the screw rod. The screw rod at least partially extends into the through hole.

In some embodiments, the screw rod corresponds to at least two fixing seats, and the fixing seats on one screw rod are arranged at intervals along the first direction.

In some embodiments, there are two screw rods, and the two screw rods are arranged at intervals along a direction perpendicular to the extension direction of the screw rod.

In some embodiments, the transmission assembly includes: a driving part and a pair of bevel gears. The driving part is connected to the inner movable plate through the pair of bevel gears.

In some embodiments, along the second direction, a slide groove is provided on the inner side of the fixed frame, and the slide groove cooperates with the inner movable plate.

In a second aspect, embodiments of the present disclosure provide a display device, including the slidable and rollable device described in any one embodiment of the first aspect, and also including a flexible display module. The flexible display module is at least partially arranged on one side of the first supporting structure and the second supporting structure in the slidable and rollable device. The slidable and rollable device can assist the flexible display module in sliding, rolling-up and opening.

In some embodiments, the flexible display module includes: a flexible display panel and a flexible circuit board connected to the flexible display panel.

A side of the flexible display panel away from the flexible circuit board is connected to the movable frame, and a side of the flexible circuit board away from the flexible display panel is connected to the inner movable panel.

In some embodiments, the second side of the flexible display module is bent around the outer surface of the roller at a preset angle and fixed to the inner movable plate, and the preset angle ranges from 210° to 230°.

### BRIEF DESCRIPTION OF THE DRAWINGS

In order to more clearly illustrate the technical solutions in the embodiments of the present disclosure, the drawings required for use in the description of the embodiments will be briefly introduced below. Obviously, the drawings described below are only some embodiments of the present disclosure. For those of ordinary skill in the art, other drawings can be obtained based on these drawings without paying any creative work.

FIG. 1 is a schematic diagram of a three-dimensional structure of a slidable and rollable device in a rolled-up state provided by an embodiment of the present disclosure.

FIG. 2 is a schematic diagram of a three-dimensional structure of a slidable and rollable device in an open state provided by an embodiment of the present disclosure.

FIG. 3 is a schematic diagram of a three-dimensional structure of a slidable and rollable device installed with a flexible display module in a rolled-up state provided by an embodiment of the present disclosure.

FIG. 4 is a schematic diagram of a three-dimensional structure of a slidable and rollable device installed with a flexible display module in an open state provided by an embodiment of the present disclosure.

FIG. 5 is a schematic principle diagram of a slidable and rollable device in a rolled-up state provided by an embodiment of the present disclosure.

FIG. 6 is a schematic principle diagram of a slidable and rollable device in an open state provided by an embodiment of the present disclosure.

FIG. 7 is a schematic structural diagram inside a fixed frame provided in an embodiment of the present disclosure.

FIG. 8 is a schematic structural diagram inside an outer frame in a rolled-up state provided by an embodiment of the present disclosure.

FIG. 9 is a schematic structural diagram inside an outer frame in an open state provided by an embodiment of the present disclosure.

FIG. 10 is a schematic structural diagram of a movable frame in a rolled-up state provided by an embodiment of the present disclosure.

FIG. 11 is a schematic structural diagram of a movable frame in an open state provided by an embodiment of the present disclosure.

FIG. 12 is a schematic structural diagram of an inner movable plate in a rolled-up state provided by an embodiment of the present disclosure.

FIG. 13 is a schematic structural diagram of an inner movable panel in an open state provided by an embodiment of the present disclosure.

FIG. 14 is a schematic structural diagram of a flexible display module in a rolled-up state provided by an embodiment of the present disclosure.

FIG. 15 is a schematic structural diagram of a flexible display module in an open state provided by an embodiment of the present disclosure.

FIG. 16 is a schematic structural diagram of a driving mechanism and a guiding mechanism in a rolled-up state provided in an embodiment of the present disclosure.

FIG. 17 is a schematic structural diagram of a driving mechanism and a guiding mechanism in an open state provided in an embodiment of the present disclosure.

Reference numbers: 1—flexible display module; 11—flexible display panel; 12—flexible circuit board; 13—first side; 14—second side; 2—outer frame; 21—fixed frame; 211—first supporting structure; 2111—first strip—shaped supporting member; 22—movable frame; 221—second supporting structure; 2211—second strip—shaped supporting member; 23—slide groove; 3—roller; 31—rotating shaft; 32—outer surface; 4—inner movable plate; 5—driving mechanism; 51—driving part; 52—transmission assembly; 521—screw rod; 522—fixed seat; 53—installation cavity; 6—guiding mechanism; 61—first rack; 62—second rack; 63—gear.

### DETAILED DESCRIPTION

In order to make the purpose, technical solutions and advantages of the present disclosure more clear, the present disclosure will be further described in detail below in conjunction with the accompanying drawings. Obviously, the described embodiments are only part of the embodiments of the present disclosure, rather than all the embodiments. Based on the embodiments in the present disclosure, all other embodiments obtained by those of ordinary skill in the art without making any creative work shall fall within the protection scope of the present disclosure.

The frame form of the slidable and rollable display device currently studied is mostly a U-shaped, sliding and rolling form. The disadvantage of the U-shaped, sliding and rolling form is that the amount of displacement is large. Because the action process of the slidable and rollable device makes the interlayer displacement mode of the flexible display module 1 different from that in the foldable display device, the risk of interlayer delamination of the flexible display module 1 in the slidable and rollable device is higher than that of the flexible display module 1 in the foldable display device. The main reason for the displacement of the flexible display module 1 is that the reverse warping after bending is flattened. In order to cater to the reverse warping characteristics, i.e., the reverse warping being not straightened or flattened, to effectively reduce the amount of interlayer displacement, and to reduce the risk of delamination failure, the present disclosure proposes the following solutions.

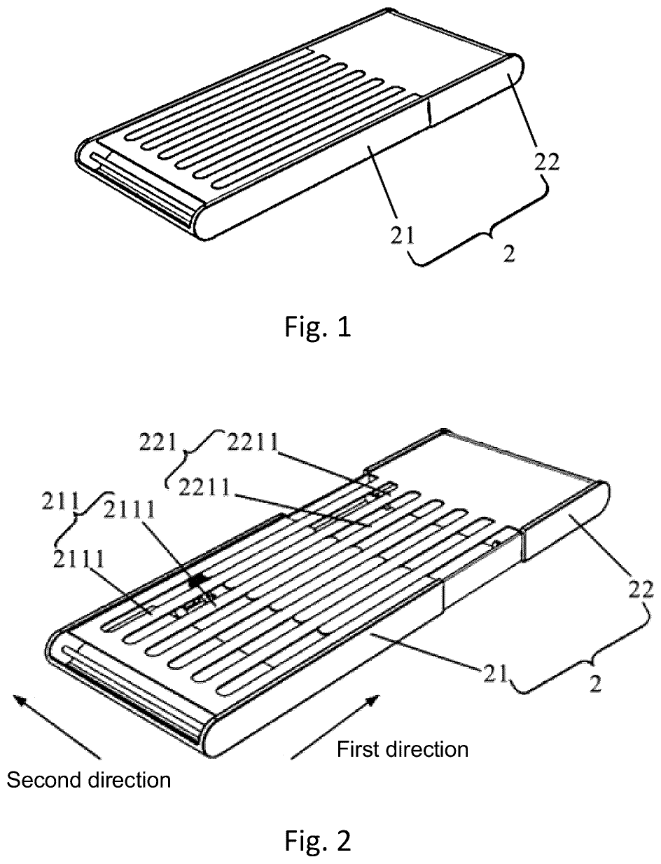

FIGS. 1 and 2 are schematic structural diagrams of a slidable and rollable device moving from a rolled-up state to an open state provided in an embodiment of the present disclosure. The movable frame 22 is buckled on the fixed frame 21, so that the movable frame 22 can slide back and forth along a first direction relative to the fixed frame 21, thereby realizing the opening and reeling-up of the slidable and rollable device.

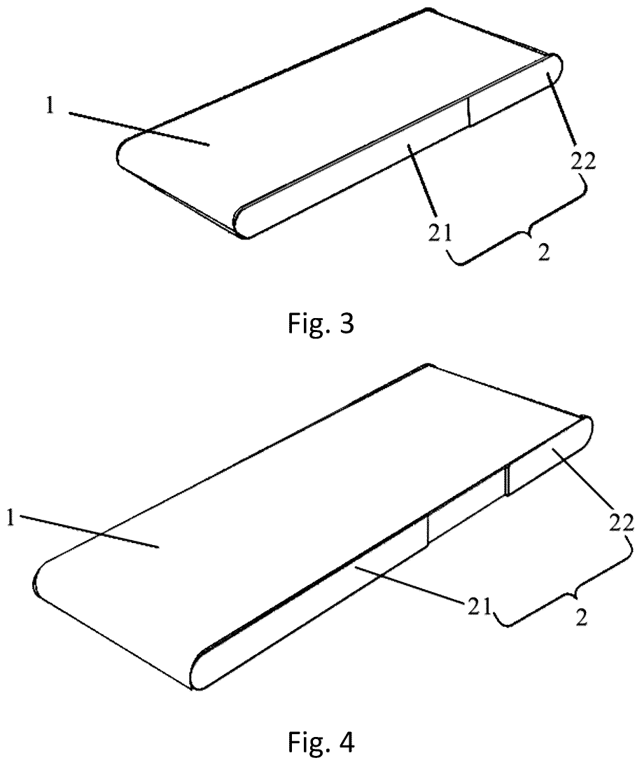

For ease of understanding, further refer to FIGS. 3 and 4, which are schematic diagrams of a slidable and rollable device installed with a flexible display module 1 provided in an embodiment of the present disclosure. In FIG. 3, the slidable and rollable device is in a rolled-up state, and the display area of the flexible display module 1 is relatively small, for example, as the size of a mobile phone. In FIG. 4, the slidable and rollable device is in an open state, and the flexible display module 1 is unfolded to a larger size, for example, the size of a tablet.

As shown in FIGS. 1 to 6, in a first aspect, embodiments of the present disclosure provide a slidable and rollable device for assisting a flexible display module 1 in sliding, rolling-up and opening. The slidable and rollable device includes: an outer frame 2. The outer frame 2 includes a fixed frame 21 and a movable frame 22. The movable frame 22 is configured to move relative to the fixed frame 21 along a first direction. The fixed frame 21 includes a first supporting structure 211. The movable frame 22 includes a second supporting structure 221. The first supporting structure 211 and the second supporting structure 221 are both used to set the flexible display module 1. A first supporting surface of the first supporting structure 211 facing the flexible display module 1 is coplanar with a second supporting surface of the second supporting structure 221 facing the flexible display module 1. The first direction is parallel to both the first supporting surface and the second supporting surface.

The slidable and rollable device includes: a roller 3. The roller 3 is rotatably arranged on the fixed frame 21. An outer surface 32 of the roller 3 is used to contact the flexible display module 1, so that the flexible display module 1 can slide around the roller 3.

The slidable and rollable device includes: an inner movable plate 4. The inner movable plate 4 is movably arranged on the fixed frame 21 along the first direction. Along the first direction, the flexible display module 1 has a first side 13 and a second side 14 arranged opposite to each other. The first side 13 of the flexible display module 1 is arranged on the second supporting structure 221. The second side 14 of the flexible display module 1 smoothly transits around the outer surface 32 of the roller 3 to a side of the inner movable plate 4 facing away from the first supporting structure 211, and is relatively fixed to the inner movable plate 4, so that the flexible display module 1 maintains a natural bending state.

The slidable and rollable device includes: a driving mechanism 5. The driving mechanism 5 is arranged on the fixed frame 21. The output end of the driving mechanism 5 is connected to the inner movable plate 4, so as to provide the inner movable plate 4 with a driving force to move along the first direction.

The slidable and rollable device includes: a guiding mechanism 6. The guiding mechanism 6 is arranged between the fixed frame 21 and the inner movable plate 4, so that the first supporting structure 211 of the fixed frame 21 moves relative to the inner movable plate 4 along the first direction.

It should be noted that, sliding cooperation is used between the fixed frame 21 and the movable frame 22. The fixed frame 21 has a first supporting structure 211, and the movable frame 22 has a second supporting structure 221. The first supporting structure 211 and the second supporting structure 221 arranged on the same plane are both used to support the flexible display module 1. When the movable frame 22 moves relative to the fixed frame 21, opening and rolling-up of the flexible display module 1 is realized, so that the size of the flexible display module 1 is switched between the mobile phone and the tablet. The flexible display module 1 has a first side 13 and a second side 14 that are arranged oppositely. The first side 13 of the flexible display module 1 is arranged on the second supporting structure 221 of the movable frame 22. The second side 14 of the flexible display module 1 smoothly transits around the outer surface 32 of the roller 3 to the side of the inner movable plate 4 away from the first supporting structure 211, and is relatively fixed to the inner movable plate 4. Since the second side of the flexible display module 1 is bent backward and connected to the inner movable plate 4, the natural reverse warping shape of the flexible display module 1 after bending is maintained. Since the natural reverse warping shape of the flexible display module 1 is also maintained during an unfolding process, the entire flexible display module is suffered from a smaller force during the unfolding process. When the movable frame 22 moves along the first direction relative to the fixed frame 21 to open the flexible display module 1, the first side 13 and the second side 14 of the flexible display module 1 move in opposite directions, which can ensure that the flexible display module 1 is only subjected to a small pulling during the movement of the movable frame 22, thereby reducing the interlayer displacement of the flexible display module 1, reducing the risk of interlayer delamination failure of the flexible display module 1, and further ensuring that the flexible display module 1 will not have poor display during the sliding, rolling-up and opening processes. The driving mechanism 5 provides the inner movable plate 4 with a driving force to move along the first direction, thereby ensuring that the second side 14 of the flexible display module 1 moves stably. Moreover, the driving mechanism 5 and the guiding mechanism 6 are both arranged in the outer frame 2, and the occupation ratio of remaining space in the outer frame 2 is also ensured, which facilitates the design and filling of other modules in the whole machine, and enables more rational use of the space of the slidable and rollable device provided in the present invention, while meeting the position design of the driving mechanism 5 and the guiding mechanism 6.

Continuing to refer to FIGS. 1 and 2, the first supporting structure 211 includes a plurality of first strip-shaped supporting members 2111. The plurality of first strip-shaped supporting members 2111 are arranged in parallel and spaced apart along the second direction. The second supporting structure 221 includes a plurality of second strip-shaped supporting members 2211. The plurality of second strip-shaped supporting members 2211 are arranged in cooperation with the plurality of first strip-shaped supporting members 2111, and the plurality of second strip-shaped supporting members 2211 are arranged in parallel and spaced apart along the second direction. The first direction is perpendicular to the second direction. The first strip-shaped supporting members 2111 and the second strip-shaped supporting members 2211 form mutually intersecting regions. The number of the first strip-shaped supporting members 2111 and the number of the second strip-shaped supporting members 2211 can be adjusted according to actual conditions. This ensures that when unfolding the slidable and rollable device, the back of the flexible display module 1 can also have a certain support to avoid collapse.

The cooperation structure of the first strip-shaped supporting members 2111 and the second strip-shaped supporting members 2211 can be selected at will. At least one second strip-shaped supporting member 2211 is distributed in the spacing area between any two adjacent first strip-shaped supporting members 2111. That is, for example, one second strip-shaped supporting member 2211 may be distributed in the spacing area between any two adjacent first strip-shaped supporting members 2111. Alternatively, two second strip-shaped supporting members 2211 arranged at intervals may be distributed in the spacing area between any two adjacent first strip-shaped supporting members 2111. Alternatively, three second strip-shaped supporting members 2211 arranged at intervals may be distributed in the spacing area between any two adjacent first strip-shaped supporting members 2111. The specific structural form is not limited here. Taking the structural form in which one second strip-shaped supporting member 2211 is distributed in the spacing area between two adjacent first strip-shaped supporting members 2111 in FIG. 2 as an example, it is ensured that the plane formed by the first supporting structure 211 and the second supporting structure 221 is more evenly stressed, and the supporting effect on the flexible display module 1 is good, so as to avoid affecting the performance of the flexible display module 1 due to different stresses on the first supporting structure 211 and the second supporting structure 221 used to support the flexible display module 1 during the rolling and opening process of the slidable and rollable device.

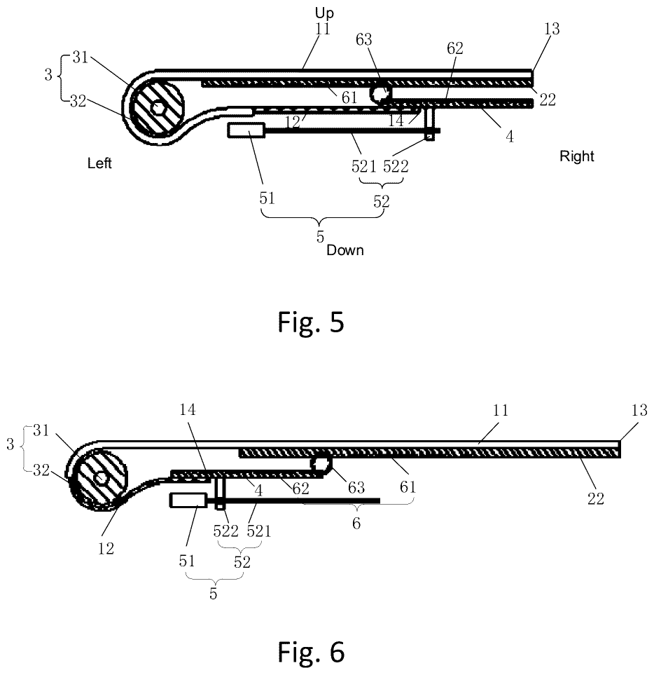

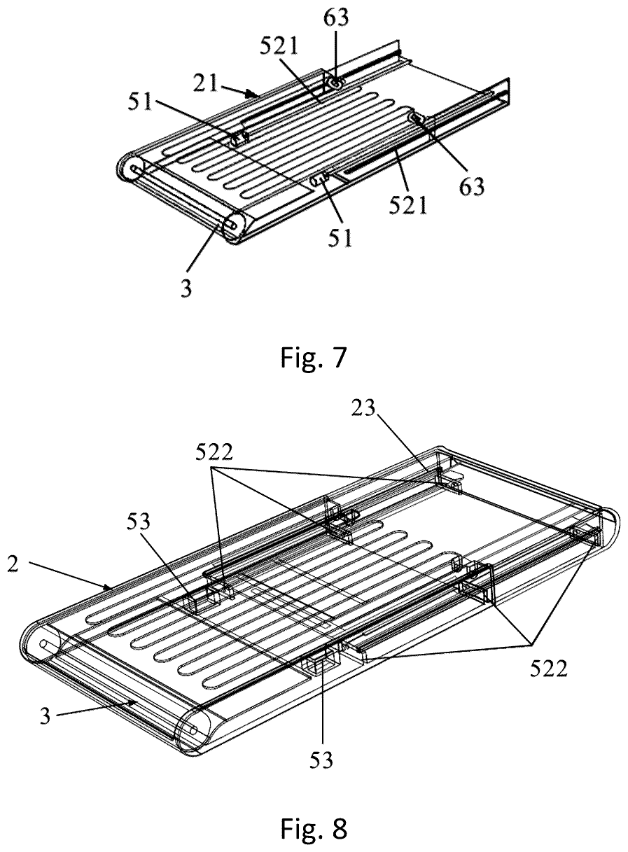

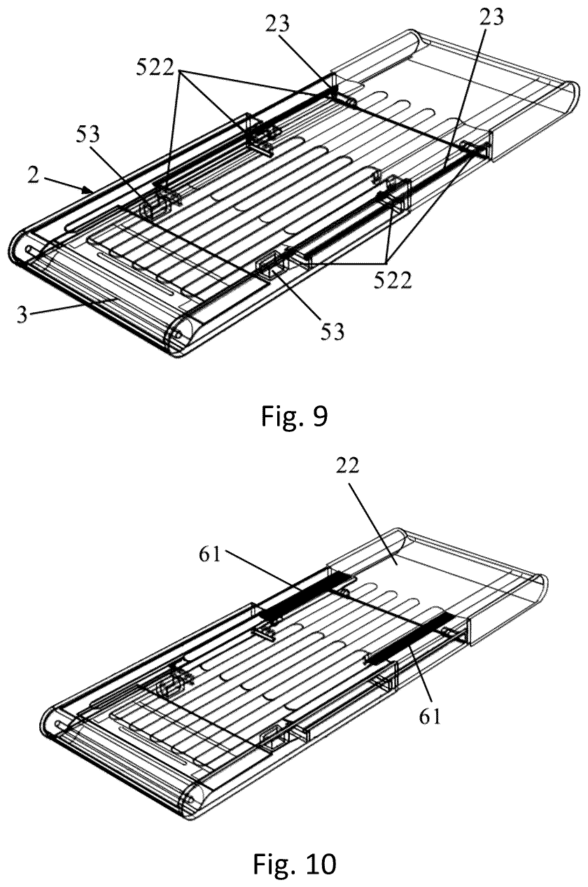

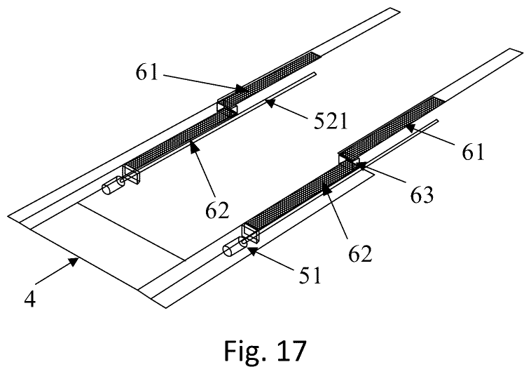

As shown in FIGS. 7 and 9, in combination with FIGS. 5 and 6, and FIGS. 16 and 17, the driving mechanism 5 includes a driving part 51 and a transmission assembly 52. The driving part 51 and the transmission assembly 52 are both arranged on the fixed frame 21. The driving part 51 is connected to the inner movable plate 4 through the transmission assembly 52. For example, the driving part 51 may be an electrode or a motor. In order to stably install the driving part 51, the driving part 51 is installed in the installation cavity 53.

In some embodiments, the transmission assembly 52 includes: a screw rod 521 and a fixed seat 522 arranged corresponding to the screw rod 521. The screw rod 521 extends along the first direction. The fixed seat 522 is arranged on the inner movable plate 4. The fixed seat 522 with a screw thread is arranged at the bottom of the inner movable plate 4. The fixed seat 522 is provided with a through hole penetrating through the fixed seat 522 along the extension direction of the screw rod 521. The inner wall of the through hole is formed with the screw thread matching the screw rod 521. The screw rod 521 at least partially extends into the through hole. A screw rod 521 passes through the through hole with the screw thread. One end of the screw rod 521 is directly connected to the output end of the driving part 51. The driving part 51, the screw rod 521, the fixed seat 522, and the roller 3 are all fixedly installed on the fixed frame 21. The transmission assembly 52 is placed on both sides of the slidable and rollable device provided in the embodiments of the present disclosure in the second direction, so as to reduce the occupation ratio of the transmission assembly 52 in the outer frame 2 and thus to save space.

As shown in FIG. 7, in combination with FIG. 8, the screw rod 521 corresponds to at least two fixing seats 522. The fixing seats 522 on one screw rod 521 are arranged at intervals along the first direction. For example, there may be two or three fixing seats 522. Regardless of the number of fixing seats 522, the distance between any adjacent fixing seats 522 is the same. In this way, the forces exerted by the fixing seats 522 in supporting the screw rod 521 are the same, so as to effectively prevent the screw rod 521 from being deformed.

In some implementations, there are two screw rods 521, and the two screw rods 521 are spaced apart in a direction perpendicular to the extension direction of the screw rod 521. Here, the extension direction of the screw rod 521 is the moving direction of the movable frame 22. The two screw rods 521 are respectively arranged at the edge positions of the slidable and rollable device provided in the embodiments of the present disclosure. The advantage of the transmission of the screw rod 521 is that it runs smoothly, does not require high torque from the driving part 51, such as a motor, and can be transmitted with relatively low power. It can also self-lock so that the screen will not be stretched or retracted due to accidental manual touch.

In some other implementations, the transmission assembly 52 includes: a driving portion 51 and a pair of bevel gears. The driving portion 51 is connected to the inner movable plate 4 through the pair of bevel gears. The advantages of the transmission assembly 52 with the bevel gears 63 are that the transmission speed is fast, the direction of the output shaft of the driving part 51 can be placed arbitrarily, and the spatial structure is small, so the spatial freedom degree inside the outer frame 2 is high.

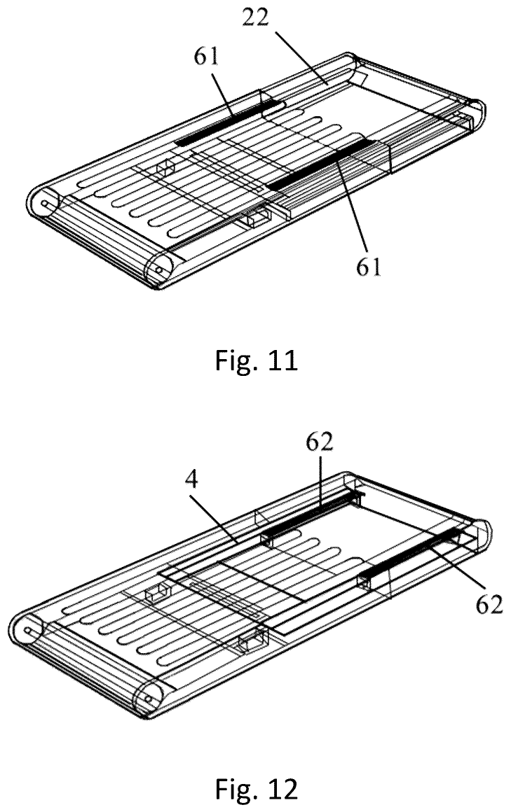

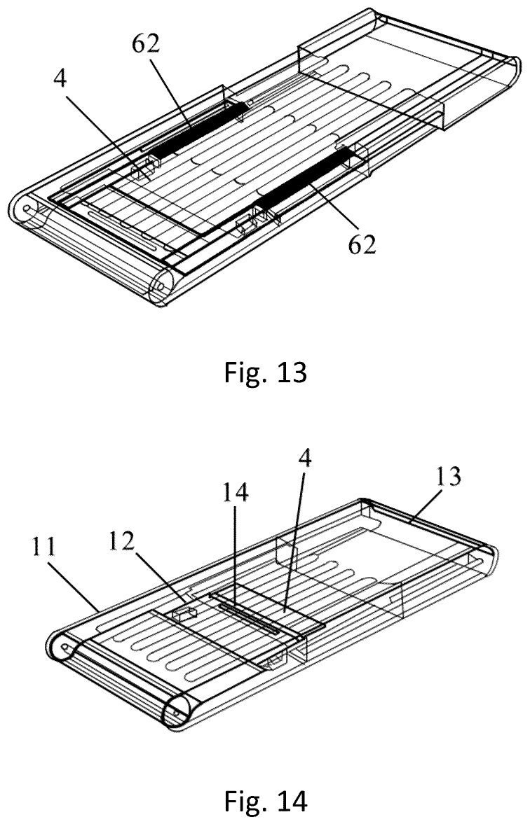

As shown in FIGS. 10 to 13, and with reference to FIGS. 5 and 6, the guiding mechanism 6 between the fixed frame 21 and the inner movable plate 4 includes: a first rack 61 and a second rack 62 arranged corresponding to the first rack 61. The extension direction of the first rack 61 is parallel to the first direction. The first rack 61 is arranged on a side surface of the movable frame 22 away from the first supporting structure 211. The second rack 62 is arranged on a side surface of the inner movable plate 4 facing the first rack 61. The orthographic projection of the first rack 61 on the second rack 62 at least partially overlaps with the second rack 62. The orthographic projection of the first rack 61 on the second rack 62 can be at least partially overlaps with the second rack 62 along the first direction, and can also be at least partially overlaps with the second rack 62 along the second direction. The guiding mechanism 6 further includes a gear 63. The gear 63 is rotatably arranged on the moving frame 22. The gear 63 is relatively fixed to the moving frame 22. The gear 63 is meshed with the first rack 61 and the second rack 62 respectively.

In order to ensure the effectiveness of the transmission of the first rack 61 and the second rack 62, the end surface of the first rack 61 and the end surface of the second rack 62 are flush along the second direction.

Continuing to refer to FIGS. 10-13, there are two first racks 61 fixedly mounted on the movable frame 22, and there are also two second racks 62 corresponding to the first racks 61. The second racks 62 are mounted on the side of the inner movable plate 4 facing the first racks 61. The two first racks 61 are spaced apart along the second direction, and the second racks 62 are spaced apart along the second direction. The first racks 61 and the second racks 62 are both arranged on both sides of the overall frame of the slidable and rollable device along the second direction, which can ensure the consistency of the relative movement of the racks on the both sides, so that the slidable and rollable device provided by the embodiments of the present disclosure is more stable during the movement, and the smoothness of the unfolding process is improved.

For ease of understanding, the movement process of the slidable and rollable device provided in the embodiments of the present disclosure is described below. Continuing to refer to the schematic diagrams shown in FIGS. 5 and 6, the schematic diagrams show the rolled-up state and the open state of the slidable and rollable device. The first side 13 of the flexible display module 1 is fixed on the movable frame 22. The second side 14 of the flexible display module 1, that is, one side of the flexible circuit board 12, passes around the outer surface 32 of the roller 3 by about 210° to 230°, then naturally bends backward and is fixed on the inner movable plate 4. The roller 3 is rotatably fixed on the fixed frame 21 through the rotating shaft 31. The extension direction of the rotating shaft 31 is parallel to the second direction. The inner movable plate 4 is parallel to the mounting surface of the first rack 61 on the movable frame 22. In this way, the flexible display module 1 forms a “U+S” shape. The first rack 61 is fixedly mounted at the bottom of the movable frame 22. A second rack 62 is fixedly mounted at the top of the inner movable plate 4. The first rack 61 and the second rack 62 are coupled together by a gear 63. A fixing seat 522 with a screw thread is arranged at the bottom of the inner movable plate 4. A transmission screw rod 521 passes through a through hole with the screw thread. One end of the screw rod 521 is directly connected to the output end of the driving part 51. The driving part 51, the screw rod 521, the fixing seat 522, and the roller 3 are all fixedly installed on the fixed frame 21. The inner movable plate 4 is arranged in a horizontal slide groove 23 of the fixed frame 21. That is, along the second direction, the slide groove 23 is arranged on the inner side of the fixed frame 21. The slide groove 23 cooperates with the inner movable plate 4. In the initial rolled-up state, the rack area of the first rack 61 is on the left side of the gear 63, and the rack area of the second rack 62 is on the right side of the gear 63. When unfolding the slidable and rollable device, the driving part 51 is started, driving the screw rod 521 to rotate, so that the fixed seat with the screw thread and the inner movable plate 4 slide to the left. The second rack 62 on the inner movable plate 4 drives the gear 63 to rotate clockwise, thereby driving the movable frame 22 and the first rack 61 to slide to the right. According to the characteristics of the rack transmission of the gear 63, the sliding strokes of the movable frame 22 and the inner movable plate 4 are equal, so that the flexible display module 1 itself will not have the risk of elongation and breakage. When folding the slidable and rollable device, similar to the unfolding process, the driving part 51 rotates in an opposite direction, driving the movable frame 22 to slide to the left, and the inner movable plate 4 to slide to the right, and finally completing the folding process.

In a second aspect, a display device provided by embodiments of the present disclosure includes any one of the slidable and rollable devices in the first aspect, and also includes a flexible display module 1. The flexible display module 1 is at least partially arranged on one side of the first supporting structure 211 and the second supporting structure 221 in the slidable and rollable device. The slidable and rollable device can assist the flexible display module 1 in sliding, rolling-up and opening.

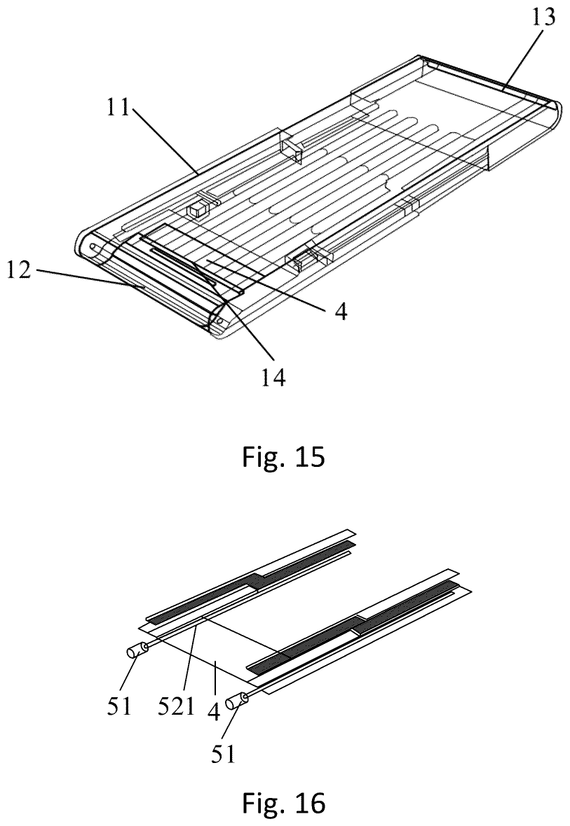

As shown in FIG. 14 and FIG. 15, the flexible display module 1 further includes: a flexible display panel 11 and a flexible circuit board 12 connected to the flexible display panel 11.

The side of the flexible display panel 11 away from the flexible circuit board 12 is connected to the movable frame 22. The side of the flexible circuit board 12 away from the flexible display panel 11 is connected to the inner movable panel 4. That is, the first side 13 of the flexible display module 1 is fixed on the movable frame 22. The second side 14, i.e., the flexible circuit board 12, passes around the outer surface 32 of the roller and enters the interior of the fixed outer frame 2 and is fixed on the inner movable plate 4. In this way, during the unfolding of the flexible display panel 11, the flexible circuit board 12 can be dragged in the reverse direction by the inner movable plate 4.

Based on the same inventive concept, the display device may be: a mobile phone, a tablet computer, a television, a monitor, a laptop computer, a digital photo frame, a navigator, or any other product or component with a display function. Other essential components of the display device should be understood by those skilled in the art and will not be elaborated herein and should not be construed as limiting the present disclosure.

Obviously, those skilled in the art can make various changes and modifications to the present disclosure without departing from the spirit and scope of the present disclosure. Thus, if these modifications and variations of the present disclosure fall within the scope of the claims of the present disclosure and their equivalents, the present disclosure is intended to include these modifications and variations.

1. A slidable and rollable device for assisting a flexible display module in sliding, rolling-up and opening, comprising:
an outer frame comprising:
a fixed frame, and
a movable frame,
wherein the movable frame is configured to move relative to the fixed frame along a first direction;
the fixed frame comprises a first supporting structure, the movable frame comprises a second supporting structure, the first supporting structure and the second supporting structure are both configured to set the flexible display module;
a first supporting surface of the first supporting structure facing the flexible display module is coplanar with a second supporting surface of the second supporting structure facing the flexible display module; and
the first direction is parallel to the first supporting surface and the second supporting surface;
a roller rotatably arranged on the fixed frame; wherein an outer surface of the roller is used for contacting the flexible display module, so that the flexible display module is slidable around the roller;
an inner movable plate movably arranged on the fixed frame along the first direction; wherein the flexible display module is provided with a first side and a second side arranged opposite to each other along the first direction, the first side of the flexible display module is arranged on the second supporting structure, the second side of the flexible display module smoothly transits around the outer surface of the roller to a side of the inner movable plate away from the first supporting structure, and is relatively fixed to the inner movable plate, so that the flexible display module maintains a natural bending state;
a driving mechanism arranged on the fixed frame; wherein an output end of the driving mechanism is connected to the inner movable plate, and is configured to provide a driving force for the inner movable plate to move along the first direction;
a guiding mechanism arranged between the fixed frame and the inner movable plate and configured for enabling the first supporting structure to move relative to the inner movable plate along the first direction.

2. The slidable and rollable device according to claim 1, wherein:
the first supporting structure comprises a plurality of first strip-shaped supporting members, the plurality of first strip-shaped supporting members are arranged in parallel and spaced apart along a second direction;
the second supporting structure comprises a plurality of second strip-shaped supporting members, the plurality of second strip-shaped supporting members are arranged in cooperation with the plurality of first strip-shaped supporting members, and the plurality of second strip-shaped supporting members are arranged in parallel and spaced apart along the second direction;
the first direction is perpendicular to the second direction.

3. The slidable and rollable device according to claim 2, wherein at least one of the second strip-shaped supporting members is distributed in a spacing area between any two adjacent first strip-shaped supporting members.

4. The slidable and rollable device according to claim 1, wherein:
the guiding mechanism comprises:
a first rack, and
a second rack arranged corresponding to the first rack;
wherein an extension direction of the first rack is parallel to the first direction, and the first rack is arranged on a side surface of the movable frame away from the first supporting structure;
the second rack is arranged on a side surface of the inner movable plate facing the first rack; and
an orthographic projection of the first rack on the second rack at least partially overlaps with the second rack;
the guiding mechanism further comprises:
a gear rotatably arranged on the moving frame, relatively fixed to the moving frame, and meshed with the first rack and the second rack.

5. The slidable and rollable device according to claim 4, wherein along a second direction, an end surface of the first rack and an end surface of the second rack are flush.

6. The slidable and rollable device according to claim 5, wherein a quantity of the first racks is two and a quantity of the second racks is two;
the two first racks are arranged at intervals along the second direction, and the two second racks are arranged at intervals along the second direction.

7. The slidable and rollable device according to claim 1, wherein the driving mechanism comprises:
a driving part, and
a transmission assembly,
wherein the driving part and the transmission assembly are both arranged on the fixed frame;
the driving part is connected to the inner movable plate through the transmission assembly.

8. The slidable and rollable device according to claim 7, wherein the transmission assembly comprises:
a screw rod, and
a fixed seat arranged corresponding to the screw rod,
wherein the screw rod extends along the first direction;
the fixed seat is arranged on the inner movable plate, the fixed seat is provided with a through hole along an extension direction of the screw rod, an inner wall of the through hole is formed with a screw thread matching the screw rod;
the screw rod at least partially extends into the through hole.

9. The slidable and rollable device according to claim 8, wherein the screw rod corresponds to at least two fixing seats, the fixing seats on one screw rod are arranged at intervals along the first direction.

10. The slidable and rollable device according to claim 8, a quantity of the screw rod is two, and the two screw rods are arranged at intervals along a direction perpendicular to the extension direction of the screw rod.

11. The slidable and rollable device according to claim 7, wherein the transmission assembly comprises:
a driving part, and
a pair of bevel gears,
wherein the driving part is connected to the inner movable plate through the pair of bevel gears.

12. The slidable and rollable device according to claim 2, wherein, along the second direction, a sliding groove is provided on an inner side of the fixed frame, the sliding groove cooperates with the inner movable plate.

13. A display device, comprising the slidable and rollable device according to claim 1 and the flexible display module;
wherein the flexible display module is at least partially arranged on one side of the first supporting structure and the second supporting structure in the slidable and rollable device;
the slidable and rollable device assists the flexible display module in sliding, rolling-up and opening.

14. The display device according to claim 13, wherein the flexible display module comprises:
a flexible display panel, and
a flexible circuit board connected to the flexible display panel;
wherein a side of the flexible display panel away from the flexible circuit board is connected to the movable frame, and a side of the flexible circuit board away from the flexible display panel is connected to the inner movable panel.

15. The display device according to claim 14, wherein the second side of the flexible display module is bent around the outer surface of the roller at a preset angle and fixed to the inner movable plate; wherein the preset angle ranges from 210° to 230°.

16. The display device according to claim 13, wherein:
the first supporting structure comprises a plurality of first strip-shaped supporting members, the plurality of first strip-shaped supporting members are arranged in parallel and spaced apart along a second direction;
the second supporting structure comprises a plurality of second strip-shaped supporting members, the plurality of second strip-shaped supporting members are arranged in cooperation with the plurality of first strip-shaped supporting members, and the plurality of second strip-shaped supporting members are arranged in parallel and spaced apart along the second direction;
the first direction is perpendicular to the second direction.

17. The display device according to claim 13, wherein:
the guiding mechanism comprises:
a first rack, and
a second rack arranged corresponding to the first rack;
wherein an extension direction of the first rack is parallel to the first direction, and the first rack is arranged on a side surface of the movable frame away from the first supporting structure;
the second rack is arranged on a side surface of the inner movable plate facing the first rack; and
an orthographic projection of the first rack on the second rack at least partially overlaps with the second rack;
the guiding mechanism further comprises:
a gear rotatably arranged on the moving frame, relatively fixed to the moving frame, and meshed with the first rack and the second rack.

18. The display device according to claim 13, wherein the driving mechanism comprises:
a driving part, and
a transmission assembly,
wherein the driving part and the transmission assembly are both arranged on the fixed frame;
the driving part is connected to the inner movable plate through the transmission assembly.

19. The display device according to claim 18, wherein the transmission assembly comprises:
a screw rod, and
a fixed seat arranged corresponding to the screw rod,
wherein the screw rod extends along the first direction;
the fixed seat is arranged on the inner movable plate, the fixed seat is provided with a through hole along an extension direction of the screw rod, an inner wall of the through hole is formed with a screw thread matching the screw rod;
the screw rod at least partially extends into the through hole.

20. The display device according to claim 18, wherein the transmission assembly comprises:
a driving part, and
a pair of bevel gears,
wherein the driving part is connected to the inner movable plate through the pair of bevel gears.
